(19) United States
(12) Patent Application Publication
(10) Pub. No.: US 2006/0050577 A1
(43) Pub. Date: Mar. 9, 2006

(54) Memory module with programmable fuse element

(76) Inventor: Peter Poechmueller, Dresden (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/214,276

(22) Filed: Aug. 29, 2005

(30) Foreign Application Priority Data
Aug. 28, 2004 (DE) 102004041731.8

(51) Int. Cl. G11C 29/00

(52) U.S. Cl. 365/200

(57) ABSTRACT

The invention relates to a memory module for providing a storage capacity, comprising a printed circuit board, one or more memory components which are applied to the printed circuit board and which in each case have a regular memory area and a redundant memory area, a connecting interface for connecting the memory module to an overall system and for receiving a specific address datum, a programmable fuse element, which is applied separately on the printed circuit board and which has a programming state dependent on a programming step, and a redundancy circuit, which is connected to the fuse element and to the one or more memory components in such a way as to address the regular memory area or the redundant memory area in one of the memory components in a manner dependent on the programming state of the fuse element in the case where the specific address datum is present.

### CROSS-REFERENCE TO RELATED APPLICATIONS

This application claims foreign priority benefits under 35 U.S.C. §119 to co-pending German patent application number DE 10 2004 041 731.8, filed 28 Aug. 2004. This related patent application is herein incorporated by reference in its entirety.

### BACKGROUND OF THE INVENTION

1. Field of the Invention

The invention relates to a memory module for providing a storage capacity having one or more memory components.

2. Description of the Related Art

For their functioning, modern data processing devices require storage capacities which can be made available to them in the form of memory modules. The memory modules have interfaces, e.g., in the form of plug connectors, so that they can optionally be inserted into the data processing device to provide more storage capacity depending on the application. In order to provide a sufficiently large storage capacity, the memory modules usually have a plurality of memory components which are applied on a printed circuit board of the memory module and which can be connected via the connecting interface to the data processing device to enable the data exchange between the memory module and the data processing device.

There is a difficulty in realizing the production of memory modules having high storage capacities with a high yield. Up to 32 individual memory components or more (e.g., 32×1 Gb chips in order to realize a 4 GB memory module), are arranged in memory modules according to the prior art. The yield in the production process for such modules is increasingly becoming very small primarily on account of a technical effect in which the data retention time degrades after thermal stress (retention degradation after thermal stress).

In order to reduce the failure rate, the memory cells in the memory components are tested while still in the unsawn state, and it is attempted to identify defective memory cells whose data retention time does not exceed a specific time duration. These cells are identified as defective and replaced by redundant memory cells in a repair step. During testing, the time duration during which defect-free cells must reliably retain the stored datum is usually chosen to be greater than the time duration for the data retention time as prescribed by the specification, in order that the cells that are jeopardized on account of a possible degradation are already likewise identified in the front end and can be replaced by redundant cells. By way of example, the time duration for the data retention time with regard to which the memory cells of the memory circuits are tested is fixed at approximately twice the time duration specified in the specification.

However, dynamic random access memory (DRAM) memory cells of all known technologies are influenced by the degradation of the data retention time after thermal stress. Thermal stress occurs during the process of packaging the chips as well as during the assembly of the memory modules, which requires a soldering process. Thermal stress activates defect mechanisms and causes an alteration (reduction) of the data retention times in individual memory cells of the memory components. On account of the increasing storage density in memory modules, this effect is occurring more frequently, so that the yield in the production of the memory modules is decreasing.

In order to increase the yield in the production of memory modules, it is possible to increase the time duration for the data retention time in order, as a precaution, to replace further memory cells by redundant memory cells whose data retention time is less than the time duration with which the memory cells are tested. However, this has the effect that the overall yield of functioning memory components falls since a larger number of memory components have to be rejected as irreparable since the memory cells to be repaired exceed the number of redundant memory cells available. Furthermore, it is possible to provide repair mechanisms in the memory component which enable the memory components applied to the memory module, i.e., after the completion of the memory module, to be subjected to a repair step. Since the memory circuit is generally no longer accessible externally since it is incorporated in a housing, provision may be made, for example, for providing electrical fuse elements in the memory component as a setting possibility. The fuse elements make it possible to correct defects identified after the assembly of the memory module and to replace regular memory cells by redundant memory cells in a targeted manner by means of a programming step. However, this approach requires the provision of electrical fuse elements on the chip together with the memory circuit, which, however, requires a more complicated production method and is thus more expensive.

Moreover, the provision of electrical fuse elements impairs the design of the memory circuits since the programming of the electrical fuse elements requires special voltage levels and a separate access to the memory components at the memory module level for this purpose. An additional disadvantage of the approach with the electrical fuse elements consists in the fact that the known technological methods for producing fuse elements are not scaleable or are insufficiently scaleable if new technology generations are used. This would constantly require a new outlay for developing technologies for producing electrical fuse elements.

### SUMMARY OF THE INVENTION

It is an object of the present invention to provide a memory module which can be produced with a better production yield and which can be repaired after its assembly.

In accordance with a first aspect of the present invention, a memory module for providing a storage capacity is provided. The memory module has a printed circuit board, on which one or more memory components are applied which in each case have a regular memory area and a redundant memory area. The memory module further comprises a connecting interface for connecting the memory module to an overall system and for receiving a specific address datum identifying an address in a memory area of one of the memory components from which data are intended to be read or to which data are intended to be written. A programmable fuse element having a programming state dependent on a programming step is applied separately on the printed circuit board. Furthermore, a redundancy circuit is connected to the fuse element and to one or more memory components in such a way as to address the regular memory area or the redundant memory area in one of the memory components in a manner dependent on the programming state of the fuse element in the case where the specific address datum is present.

In accordance with a further aspect of the present invention, a memory module may be provided which has a printed circuit board, on which one or more memory components are applied, each memory component having a regular memory area. Furthermore, a separate redundant memory component having a redundant memory area is provided on the printed circuit board. In a manner dependent on a programming state of a programmable fuse element, in the case where the specific address datum is present, a redundancy circuit addresses either the corresponding regular memory area in the one or more memory components or the redundant memory area in the redundant memory component.

In accordance with a further aspect of the present invention, a memory module may be provided which has a printed circuit board, on which one or more memory components are applied. Furthermore, separate fuse elements are provided on the printed circuit board. With the aid of a redundancy circuit connected to the fuse elements and the one or more memory components, it is possible to address either the regular memory area in the one or more memory components or a redundant memory area in the redundancy circuit in a manner dependent on a programming state of the programmable fuse element in the case where the specific address datum is present.

The invention provides a memory module which provides a predetermined storage capacity and which can be inserted in an overall system, e.g., into a data processing unit with the aid of the connecting interface. One or more programmable fuse elements are provided on the memory module. The fuse elements can be programmed after the assembly of the memory module in a programming step and are connected to a redundancy circuit, so that, in the case where an address is present with which a memory cell identified as defective after the assembly of the module would be addressed, addressing is effected by a redundant memory cell or a redundant memory area in order thus to ensure the function of the memory module.

In this case, it is essential that the programmable fuse element is formed separately from the memory components. Since the memory components are generally situated in a housing, fuse elements situated in the memory component cannot be accessible externally. The fuse elements applied separately on the printed circuit board thus make it possible, even after the completion of the memory module and subsequent testing of the memory module for the purpose of identifying defective memory cells or defective memory areas, to program the fuse elements with the aid of a programming step in order to replace the defective memory cells or memory areas by memory cells or memory areas provided in redundant fashion.

The fuse element is preferably formed as a laser fuse element. Laser fuse elements can be programmed in a simple manner with the aid of a laser trimming method. Laser fuse elements generally comprise a thin line connection which can be melted or vaporized by irradiation with a laser beam in order to interrupt the line connection. An originally conductive line connection is thus severed, and it is possible to set different states depending on whether the laser fuse is conductive or nonconductive.

In accordance with one embodiment of the invention, the laser fuse element may be formed with the aid of a conductor track that is uncovered on a surface. As an alternative, the laser fuse element may be provided in a fuse component which is produced separately and which is applied on the printed circuit board, the fuse elements being uncovered for the laser process.

In particular, the redundant memory area may be formed by one or more register cells which are individually addressable.

As an alternative, the redundant memory area may be essentially constructed structurally identically to the regular memory area.

In accordance with one embodiment of the invention, the redundancy circuit may be provided in a buffer component separate from the memory components, the buffer component being arranged between the memory components and the connecting interface in order to forward data received at the connecting interface to the memory components in parallelized fashion and in order to serialize data to be transmitted by the memory components and to output them via the connecting interface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a memory module in accordance with a first embodiment of the invention, and

FIG. 2 shows a memory module in accordance with a second embodiment of the invention, and

FIG. 3 shows a memory module in accordance with a third embodiment of the invention.

### DETAILED DESCRIPTION OF THE PREFERRED EMBODIMENT

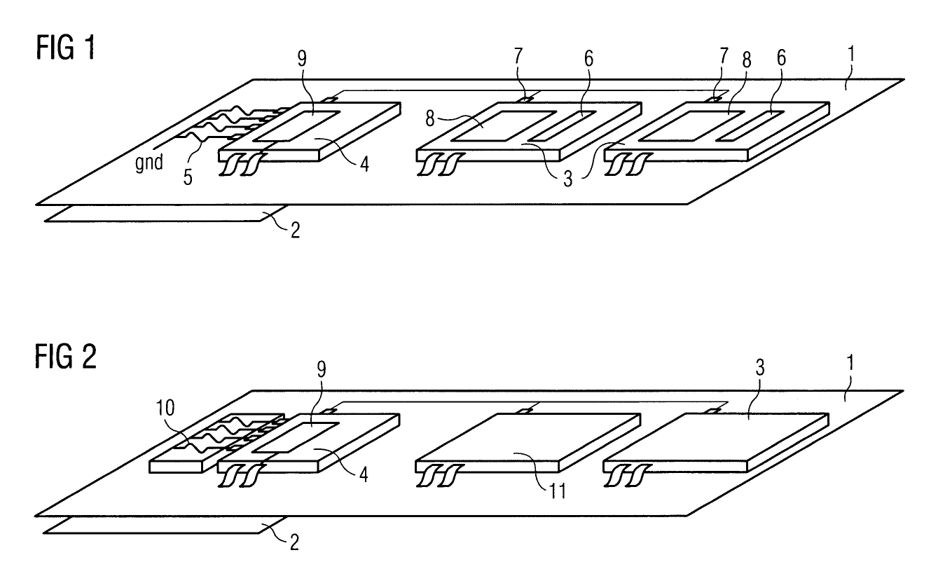

FIG. 1 illustrates a memory module in accordance with a first embodiment of the present invention. The memory module has a printed circuit board 1, which is provided with a connecting device 2 for connecting the memory module to an overall system, such as a data processing unit. The connecting device 2 is often embodied as a plug connector or as a contact strip and affords the possibility of communicating with the memory module with the aid of a large number of signals, such as memory signals, address signals, and command signals, and also of providing supply voltages to the memory module.

The connecting device 2 is connected to memory components 3 applied on the printed circuit board 1 via rewiring lines (not illustrated), so that a memory area in one of the memory components 3 is addressed in a manner dependent on applied signals. Via the connecting device 2, data can be transmitted to the relevant addressed memory component 3 or received from the addressed memory component 3. The requisite supply lines and other signal lines are not illustrated for reasons of clarity.

A redundancy circuit 4 is also situated on the printed circuit board 1, said redundancy circuit being arranged in the form of a separate component on the printed circuit board 1. Furthermore, fuse elements 5 connected to the redundancy circuit 4 are provided on the printed circuit board 1. The fuse elements 5 are formed as laser fuse elements and constitute uncovered line connections that can be isolated on the printed circuit board 1. The line connections are usually formed from a metallic material or some other material that can be severed by melting or vaporization. The severing of the line connections of the laser fuses 5 is performed with the aid of a laser trimming method in which a laser beam is focused onto one of the laser fuse elements 5 to melt or vaporize the line connection so that a conductive connection existing previously becomes nonconductive. Through the selection of those laser fuse elements 5 which are intended to be severed from a number of laser fuse elements, it is possible to perform settings that are read into the redundancy circuit 4 by detection of the conductive or nonconductive state of each of the laser fuse elements.

After the assembly of the memory module, the memory cells of the memory components are tested, and defects of individual memory cells or memory areas are ascertained. With the aid of a suitable setting of the laser fuse elements, it is possible, then, to code the addresses of the defective memory cells or memory areas, so that, given the presence of the address with the defective memory area, a redundant memory area is addressed. By way of example, each of the memory components 3 has such a redundant memory area 6, which is either made available exclusively for the repair at the memory module level or has not been used in the repair at the wafer level, i.e., in the repair of the memory circuits in the unsawn state. The redundancy circuit may also include a redundant memory area 9.

The redundant memory areas may be formed as register cells, i.e., as static random access memory (SRAM) cells, or be formed identically to the regular memory area as part of the DRAM memory cells.

The memory module is configured such that, after the supply voltage has been switched on, the redundancy circuit 4 first reads out the settings of the laser fuse elements 5 and forwards this information in a suitable manner, preferably serially to the memory components 3. For this purpose, additional connections 7 and a suitable control unit (not shown) may be provided in the memory components 3. By way of example, the transfer of the items of information read out from the laser fuse may be carried out by prescribing a clock signal for one of the memory components 3, which clock signal is communicated to the redundancy circuit 4, thereby synchronizing the transfer of the laser fuse information items to the memory components 3. Alternatively, the clock signal generated may be generated by the redundancy circuit 4 to reduce the area requirement of the memory component 3.

In any event, the control unit that is additionally present in the memory components 3 is provided such that it can receive the fuse information from the redundancy circuit 4 in a suitable manner and addresses memory areas provided in redundant fashion in a manner dependent on the received laser fuse information given the presence of a specific address prescribed by the laser fuse information.

FIG. 2 illustrates a further embodiment of the present invention. The embodiment of FIG. 2 differs from the embodiment of FIG. 1 in two aspects which are not dependent on one another. Identical elements are provided with the same reference symbols in both embodiments.

Instead of the fuse elements 5 applied on the printed circuit board 1 which are illustrated in FIG. 1, the fuse elements are provided in a separate fuse component 10 in which the fuse elements are provided. In this case, the fuse elements may also be formed as electrical fuses. In this case, no memory cell array is situated in the fuse component 10, so that technological incompatibilities between the production process for electrical fuse elements and memory elements cannot occur. By application of a suitable programming voltage, the electrical fuse elements can be programmed, i.e., altered in terms of their conductivity state, so that different programming states can be read out. Electrical fuse elements usually have a very high electrical resistance in the unaltered state, which resistance can be greatly reduced by a programming step.

However, the fuse component 10 may also have uncovered laser fuse elements which are accessible after the completion of the memory module in a laser trimming method by means of a laser beam. The layout of the printed circuit board 1 is configured such that the fuse component 10 is connected to the redundancy circuit 4 such that the redundancy circuit 4 can read out the state of the individual fuse elements of the fuse component.

An aspect that is independent thereof and may also be combined with the embodiment of FIG. 1, is that a suitable redundancy for the repair at the memory module level is not provided in each memory component 3. Instead, it may be provided that at least one of the memory components 3 applied on the memory module is provided as a redundant memory component 11 serving exclusively for the repair of defective memory cells in the other memory components 3. Such a configuration is expedient particularly when the memory module has very many memory components 3, in the case of which a large number of memory cell defects may occur or is to be expected. When the memory module is addressed, it may be provided in this case that the addresses present are checked, e.g., in the redundancy circuit 4, and, given the presence of a defective address, which may for example likewise be stored in the redundant memory component, a corresponding redundant memory cell or redundant memory area in the redundant memory component 11 is addressed.

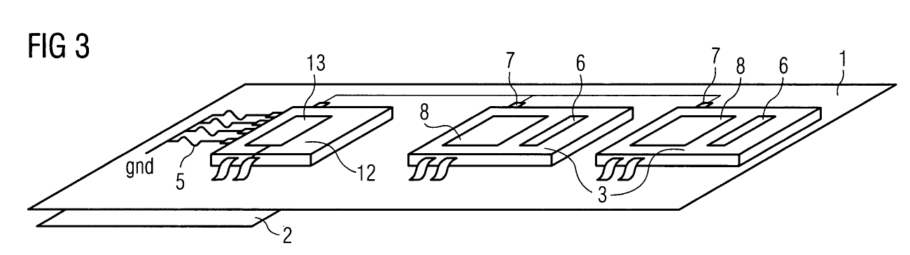

As is illustrated in FIG. 3, in accordance with a further embodiment of the invention, a buffer component 12 is provided on the printed circuit board 1 and serves for producing a point-to-point connection between a memory controller of the external overall system and the memory module. The buffer component 12 has the function of producing a very fast serial data link to the memory controller. Data received from the external system, i.e., from the memory controller, are parallelized in the buffer component and forwarded to the corresponding memory component 3. Data to be transmitted by the memory components are conducted to the buffer component 12, which serializes these data to be transmitted and transmits them to the memory controller via the connecting device 2. The redundancy circuit described above is provided the buffer component 12, so that the buffer component 12 has the information about defective memory areas in the memory components 3. The buffer component 12 may itself provide redundant memory areas 13 in order to be able to replace defective memory areas in the memory components 3. The buffer component 12 in this case receives the serial address data and compares them with defect addresses stored in the buffer component 12, e.g., in a defect address memory, in order to identify if the addressed memory area is to be replaced by one of the redundant memory areas 13.

With the provision of a buffer component combined with the above-described different variants of the memory module according to embodiments of the invention, the fuse elements may be arranged either or both on the printed circuit board 1 and in a separate component. Furthermore, the redundant memory area, instead of being arranged in the buffer component 12, may be provided both in a separate memory component for providing redundant memory areas in accordance with the embodiment of FIG. 2 and as a memory segment in the memory components 3.

While the foregoing is directed to embodiments of the present invention, other and further embodiments of the invention may be devised without departing from the basic scope thereof, and the scope thereof is determined by the claims that follow.

What is claimed is:

1. A memory module, comprising:
a printed circuit board;
one or more memory components, which are applied to the printed circuit board, each memory component having a regular memory area and a redundant memory area;
an interface for connecting the memory module to an overall system and for receiving a specific address datum;
a programmable fuse element, disposed on the printed circuit board, having a programming state dependent on a programming step; and
a redundancy circuit, connected to the fuse element and the one or more memory components, which, depending on the programming state of the fuse element, addresses one of the regular memory area and the redundant memory area corresponding to the specific address datum.

2. The memory circuit of claim 1, wherein the fuse element is a laser fuse element comprising an uncovered conductor track disposed on a surface of the printed circuit board.

3. The memory circuit of claim 1, wherein the fuse element is provided in a fuse component which is applied to the printed circuit board.

4. The memory circuit of claim 4, wherein the fuse element comprises a programmable electrical fuse.

5. The memory circuit of claim 1, wherein the redundant memory area comprises a plurality of individually addressable register cells.

6. The memory circuit of claim 1, wherein the redundant memory area is substantially identical structurally to the regular memory area.

7. The memory circuit of claim 1, wherein the redundancy circuit further comprises an additional redundant memory area.

8. The memory circuit of claim 1, wherein the redundancy circuit is disposed on the printed circuit board as a buffer component arranged between the memory components and the connecting interface, the buffer component configured to forward data received at the connecting interface to the memory components in parallelized fashion, to serialize data to be transmitted by the memory components, and to output the serialized data via the connecting interface.

9. A memory module, comprising:
a printed circuit board;
one or more regular memory components which are applied to the printed circuit board, each memory component having a regular memory area;
a redundant memory component which is applied to the printed circuit board, the redundant memory component having a redundant memory area;
an interface for connecting the memory module to an overall system and for receiving a specific address datum;
a programmable fuse element, disposed on the printed circuit board, having a programming state dependent on a programming step; and
a redundancy circuit, connected to the fuse element, the one or more memory components and the redundant memory component, which, depending on the programming state of the fuse element, addresses one of the regular memory area and the redundant memory area corresponding to the specific address datum.

10. The memory circuit of claim 9, wherein the fuse element is a laser fuse element comprising an uncovered conductor track disposed on a surface of the printed circuit board.

11. The memory circuit of claim 9, wherein the fuse element is provided in a fuse component which is applied to the printed circuit board.

12. The memory circuit of claim 11, wherein the fuse element comprises a programmable electrical fuse.

13. The memory circuit of claim 9, wherein the redundant memory component is substantially identical structurally to the regular memory component.

14. The memory circuit of claim 9, wherein the redundancy circuit further comprises an additional redundant memory area.

15. The memory circuit of claim 9, wherein the redundancy circuit is disposed on the printed circuit board as a buffer component arranged between the memory components and the connecting interface, the buffer component configured to forward data received at the connecting interface to the memory components in parallelized fashion, to serialize data to be transmitted by the memory components, and to output the serialized data via the connecting interface.

16. A memory module, comprising:
a printed circuit board;
one or more regular memory components which are applied to the printed circuit board, each memory component having a regular memory area;
an interface for connecting the memory module to an overall system and for receiving a specific address datum;
a programmable fuse element, disposed on the printed circuit board, having a programming state dependent on a programming step; and
a redundancy circuit, connected to the fuse element and the one or more memory components, comprising a redundant memory area, which, depending on the programming state of the fuse element, addresses one of the regular memory area and the redundant memory area corresponding to the specific address datum.

17. The memory circuit of claim 16, wherein the fuse element is a laser fuse element comprising an uncovered conductor track disposed on a surface of the printed circuit board.

18. The memory circuit of claim 16, wherein the fuse element is provided in a fuse component which is applied to the printed circuit board.

19. The memory circuit of claim 24, wherein the fuse element comprises a programmable electrical fuse.

20. The memory circuit of claim 16, wherein the redundancy circuit is disposed on the printed circuit board as a buffer component arranged between the memory components and the connecting interface, the buffer component configured to forward data received at the connecting interface to the memory components in parallelized fashion, to serialize data to be transmitted by the memory components, and to output the serialized data via the connecting interface.

21. A method for manufacturing a memory module, comprising:
providing a printed circuit board;
forming a programmable fuse element on the printed circuit board having a programming state dependent on a programming step;
applying one or more memory components to the printed circuit board having a regular memory area;
providing a redundant memory area;
providing an interface for connecting the memory module to an overall system and for receiving a specific address datum; and
providing a redundancy circuit, connected to the fuse element and the one or more memory components, which, depending on the programming state of the fuse element, addresses one of the regular memory area and the redundant memory area corresponding to the specific address datum.

22. The method of claim 21, wherein the fuse element is formed as a laser fuse element comprising an uncovered conductor track disposed on a surface of the printed circuit board.

23. The method of claim 21, wherein the fuse element is provided in a fuse component which is applied to the printed circuit board.

24. The method of claim 21, wherein the redundant memory area is provided in the one or more memory components.

25. The method of claim 21, wherein the redundant memory area is provided as a redundant memory component which is applied to the printed circuit board.

26. The method of claim 21, wherein the redundant memory area is provided in the one or more memory components;

27. The method of claim 21, wherein the redundancy circuit is disposed on the printed circuit board as a buffer component arranged between the memory components and the connecting interface, the buffer component configured to forward data received at the connecting interface to the memory components in parallelized fashion, to serialize data to be transmitted by the memory components, and to output the serialized data via the connecting interface.

28. The method of claim 22, wherein the redundant memory area is provided in the redundancy circuit.
